(19) United States
(12) Patent Application Publication
(10) Pub. No.: US 2026/0314393 A1
(43) Pub. Date: Oct. 8, 2026

(54) INTEGRATED PASSIVE DEVICE AND METHOD FOR MANUFACTURING THE SAME, ELECTRONIC APPARATUS

(71) Applicants: Beijing BOE Sensor Technology Co., Ltd., Beijing (CN); BOE Technology Group Co., Ltd., Beijing (CN); Beijing BOE Technology Development Co., Ltd., Beijing (CN)

(72) Inventors: Huiying LI, Beijing (CN); Yue LI, Beijing (CN); Yuelei XIAO, Beijing (CN); Yulin FENG, Beijing (CN); Yifan WU, Beijing (CN); Yingying ZHAO, Beijing (CN); Can ZHANG, Beijing (CN); Qichang AN, Beijing (CN); Shuang XU, Beijing (CN); Biqi LI, Beijing (CN); Kuili REN, Beijing (CN)

(21) Appl. No.: 18/996,704

(22) PCT Filed: May 15, 2024
(86) PCT No.: PCT/CN2024/093365

§ 371 Date: Jan. 17, 2025

(30) Foreign Application Priority Data
Jun. 21, 2023 (CN) 202310748263.X

(51) Int. Cl. H10W 20/40; H10W 20/00; H10W 20/41; H10W 20/42

(52) U.S. Cl. CPC H10W 20/497; H10W 20/057; H10W 20/083; H10W 20/084; H10W 20/42; H10W 20/435

(57) ABSTRACT

The present disclosure provides an integrated passive device, a method for manufacturing the same, and an electronic apparatus, and belongs to the technical field of passive devices. The integrated passive device includes a dielectric substrate, at least two conductive layers on the dielectric substrate, and an interlayer dielectric layer between any two adjacent conductive layers; one of any two adjacent conductive layers close to the dielectric substrate is a first conductive layer, and the other one of the any two adjacent conductive layers is a second conductive layer; the first conductive layer includes a first conductive structure, and the second conductive layer includes a second conductive structure; the second conductive structure and the first conductive structure are electrically connected to each other through a connection hole penetrating through at least the interlayer dielectric layer between the second conductive structure and the first conductive structure.

### TECHNICAL FIELD

The present disclosure belongs to the technical field of passive devices, and particularly relates to an integrated passive device, a method for manufacturing an integrated passive device, and an electronic apparatus.

### BACKGROUND

Nowadays, the consumer electronics industry is developing day by day. Mobile communication terminals represented by mobile phones, especially 5G mobile phones, are developing rapidly. The frequency bands of signals to be processed by the mobile phones are increasing, and the number of RF (radio frequency) chips required is also increasing. The form of the mobile phones enjoyed by consumers is developing continuously towards miniaturization, lightness and thinness and long power-supply durability per charging cycle. In traditional mobile phones, a large number of discrete components such as resistors, capacitors, inductors, filters, and the like exist on the RF PCB. The discrete components have the disadvantages of having relatively large volumes, relatively high power consumptions, many welded spots and relatively large changes of parasitic parameters, and thus are difficult to meet future requirements. The interconnection, matching and the like between RF chips require an integrated passive device (IPD) with a relatively small area, relatively high performance and good consistency.

### SUMMARY

The present disclosure aims to solve at least one of the technical problems of the prior art, and provides an integrated passive device, a method for manufacturing an integrated passive device, and an electronic apparatus.

In a first aspect, an embodiment of the present disclosure provides an integrated passive device, including a dielectric substrate, at least two conductive layers on the dielectric substrate, and an interlayer dielectric layer between any two adjacent ones of the at least two conductive layers; one of any two adjacent conductive layers close to the dielectric substrate is a first conductive layer, and the other one of the any two adjacent conductive layers is a second conductive layer; the first conductive layer includes a first conductive structure, and the second conductive layer includes a second conductive structure: the second conductive structure and the first conductive structure are electrically connected to each other through a connection hole penetrating through at least the interlayer dielectric layer between the second conductive structure and the first conductive structure.

In some implementations, the connection hole includes a first sub-bole and a second sub-hole communicated with each othe; the first sub-hole penetrates through the interlayer dielectric layer, and the second sub-hole penetrates through at least a part of a thickness of the first conductive structure.

In some implementations, a first opening of the first sub-hole is connected to a second opening of the second sub-hole, and orthographic projections of the first opening and the second opening on the dielectric substrate coincide each other.

In some implementations, a first opening of the first sub-hole is connected to a second opening of the second sub-hole, and an orthographic projection of the second opening on the dielectric substrate covers an orthographic projection of the first opening on the dielectric substrate.

In some implementations, a shape of an orthographic projection of the second sub-hole on the dielectric substrate includes a circle or a square.

In some implementations, an inner wall of the connection hole is stepped.

In some implementations, the connection hole includes a plurality of sub-holes communicated with each othe, any two adjacent ones of the plurality of sub-holes define a step at a connection position therebetween, and a maximum aperture of the sub-hole closer to the dielectric substrate is less than a minimum aperture of the sub-hole farther from the dielectric substrate.

In some implementations, the connection hole penetrats through only the interlayer dielectric layer.

In some implementations, the first conductive structure includes a first body structure and a first bump structure connected to a side of the first body structure close to the interlayer dielectric layer; and/or the second conductive structure includes a second body structure and a second bump structure connected to a side of the second body structure close to the interlayer dielectric layer.

In some implementations, the first conductive structure includes the first body structure and the first bump structure, the second conductive structure includes the second body structure and the second bump structure, and the first body structure and the second body structure are connected to each other through the connection hole.

In some implementations, the first conductive structure includes the first body structure and the first bump structure, the second conductive structure includes the second body structure and the second bump structure, and orthographic projections of the first bump structure and the second bump structure on the dielectric substrate are alternately arranged.

In some implementations, the first conductive structure includes the first body structure and the first bump structure, the second conductive structure includes the second body structure and the second bump structure, and the first bump structure and the second bump structure are in one-to-one correspondence.

In some implementations, the interlayer dielectric layer includes a third body structure, a third bump structure connected to a side of the third body structure close to the first conductive structure, and a fourth bump structure connected to a side of the third body structure close to the second conductive structure.

In some implementations, a material of the interlayer dielectric layer includes polyimide.

An embodiment of the present disclosure provides a method for manufacturing an integrated passive device, including: providing a dielectric substrate, forming at least two conductive layers on the dielectric substrate, and forming an interlayer dielectric layer between any two adjacent ones of the at least two conductive layers; one of any two adjacent conductive layers close to the dielectric substrate is a first conductive layer, and the other one of the any two adjacent conductive layers is a second conductive layer; forming the first conductive layer includes forming a first conductive structure, forming the second conductive layer includes forming a second conductive structure, and the second conductive structure and the first conductive structure are electrically connected to each other through a connection hole penetrating through at least the interlayer dielectric layer between the second conductive structure and the first conductive structure.

In some implementations, forming the connection hole includes: patterning, before forming the interlayer dielectric layer, a first conductive pattern, to form a second sub-hole penetrating through at least a part of a thickness of the first conductive pattern; and forming, after forming the interlayer dielectric layer, a first sub-hole penetrating through the interlayer dielectric layer, the first sub-hole and the second sub-hole are communicated with each other to form the connection hole.

In some implementations, forming the interlayer dielectric layer includes sequentially stacking first interlayer dielectric sub-layers along a direction away from the dielectric substrate; each of the first interlayer dielectric sub-layers is provided with a sub-hole, and sub-holes of the first interlayer dielectric sub-layers are communicated with each other to form the connection hole; any two adjacent ones of the sub-holes define a step at a connection position therebetween, and a maximum aperture of the sub-hole closer to the dielectric substrate is less than a minimum aperture of the sub-hole farther from the dielectric substrate.

In some implementations, the first conductive structure includes a first body structure, and a first bump structure connected to a side of the first body structure close to the interlayer dielectric layer; and/or the second conductive structure includes a second body structure and a second bump structure connected to a side of the second body structure close to the interlayer dielectric layer.

In some implementations, the conductive layer is formed through an electroplating process.

In a second aspect, an embodiment of the present disclosure provides an electronic apparatus including the integrated passive device described above.

### BRIEF DESCRIPTION OF DRAWINGS

FIG. 1 is a cross-sectional view illustrating a part of an integrated passive device according to an embodiment of the present disclosure.

FIG. 2 is a cross-sectional view illustrating a connection hole of the integrated passive device shown in FIG. 1.

FIG. 3 is a cross-sectional view illustrating a part of an integrated passive device in a first example according to an embodiment of the present disclosure.

FIG. 4a is a cross-sectional view illustrating a connection hole of the integrated passive device shown in FIG. 3.

FIG. 4b is a cross-sectional view illustrating a connection hole of the integrated passive device shown in FIG. 3.

FIG. 5 is a cross-sectional view illustrating a part of an integrated passive device including three conductive layers in a first example according to an embodiment of the present disclosure.

FIG. 6 is a flowchart illustrating a method for manufacturing an integrated passive device in a first example according to an embodiment of the present disclosure.

FIG. 7 is a cross-sectional view illustrating a part of an integrated passive device in a second example according to an embodiment of the present disclosure.

FIG. 8 is a cross-sectional view illustrating a connection hole of the integrated passive device shown in FIG. 7.

FIG. 9 is a cross-sectional view illustrating a part of an integrated passive device including three conductive layers in a second example according to an embodiment of the present disclosure.

FIG. 10 is a flowchart illustrating a method for manufacturing an integrated passive device in a second example according to an embodiment of the present disclosure.

FIG. 11 is a cross-sectional view illustrating a part of an integrated passive device in a third example according to an embodiment of the present disclosure.

FIG. 12 is a cross-sectional view illustrating a part of another integrated passive device in a third example according to an embodiment of the present disclosure.

FIG. 13 is a cross-sectional view illustrating a part of an integrated passive device including three conductive layers in a third example according to an embodiment of the present disclosure.

FIG. 14 is a flowchart illustrating a method for manufacturing an integrated passive device in a third example according to an embodiment of the present disclosure.

### DETAIL DESCRIPTION OF EMBODIMENTS

In order to enable one of ordinary skill in the art to better understand the technical solutions of the present disclosure, the present disclosure is further described below in detail with reference to the accompanying drawings and exemplary embodiments.

Unless defined otherwise, technical or scientific terms used herein shall have the ordinary meaning as understood by one of ordinary skill in the art to which the present disclosure belongs. The words “first”, “second”, and the like used in the present disclosure do not denote any order, quantity, or importance, but rather distinguish one element from another. Likewise, the word “a”, “an”, “the”, or the like does not denote a limitation of quantity, but rather denotes the presence of at least one element. The word “comprising”, “including”, or the like, means that the element or item preceding the word contains the element or item listed after the word and its equivalent, but does not exclude other elements or items. The term “connected”, “coupled”, or the like is not restricted to physical or mechanical connections, but may includes electrical connections, whether direct or indirect connections. Terms “upper/on”, “lower/below”, “left”, “right”, and the like are used only to indicate relative positional relationships, and when the absolute position of the object being described is changed, the relative positional relationships may be changed accordingly.

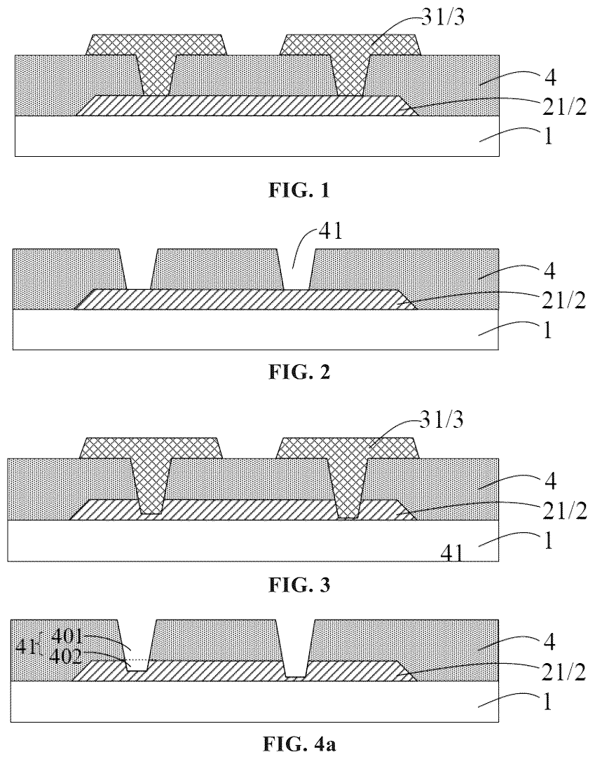

FIG. 1 is a cross-sectional view illustrating a part of an integrated passive device according to an embodiment of the present disclosure; and FIG. 2 is a cross-sectional view illustrating a connection hole of the integrated passive device shown in FIG. 1. In a first aspect, as shown in FIGS. 1 and 2, an embodiment of the present disclosure provides an integrated passive device, which includes, but is not limited to, an inductor. The device includes a dielectric substrate 1, at least two conductive layers on the dielectric substrate 1, and an interlayer dielectric layer 4 between any two adjacent conductive layers. In an embodiment of the present disclosure, for any two adjacent conductive layers, one of the two adjacent conductive layers is referred to as a first conductive layer 2, and the other of the two adjacent conductive layers is referred to as a second conductive layer 3. The first conductive layer 2 includes a first conductive structure 21, the second conductive layer 3 includes a second conductive structure 31, and the first conductive structure 21 and the second conductive structure 31 are electrically connected to each other through a connection hole 41 penetrating through at least the interlayer dielectric layer 4 between the first conductive structure 21 and the second conductive structure 31.

It should be noted that, in a case where the integrated passive device is an inductor, the first conductive structure 21 and the second conductive structure 31 are coil structures of the inductor, and the number of turns of the coil structures of the inductor is determined by the number of conductive layers.

In an embodiment of the present disclosure, a material of the conductive layer generally includes a metal material, a material of the interlayer dielectric layer 4 includes, but is not limited to, polyimide PI, and in the embodiment of the present disclosure, only the interlayer dielectric layer 4 made of polyimide is used as an example for explanation. Since a difference between the thermal expansion coefficients of the materials of the conductive layer and the interlayer dielectric layer 4 is relatively large, if any film layer expands due to heated, the interlayer dielectric layer 4 expands laterally (in parallel to a plane where the dielectric substrate 1 is located), so that separation (peeling) occurs at the connection position between the first conductive structure 21 and the second conductive structure 31, which are electrically connected together originally. The following technical solutions are provided in embodiments of the present disclosure to improve this problem.

Before the following examples are described, it should be noted that only two adjacent conductive layers electrically connected together are mainly used as an example in the following examples, but it should be understood that the integrated passive device may have more conductive layers, which are not listed here.

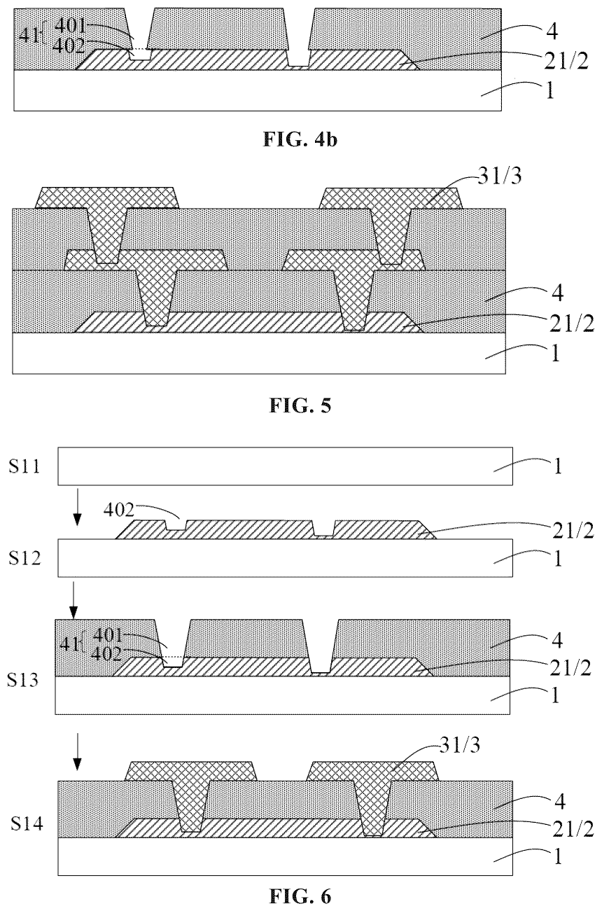

FIG. 3 is a cross-sectional view illustrating a part of an integrated passive device in a first example according to an embodiment of the present disclosure; and FIG. 4a is a cross-sectional view illustrating a connection hole of the integrated passive device shown in FIG. 3. As shown in FIGS. 3 and 4a, in the first example, the integrated passive device includes a dielectric substrate 1, and a first conductive layer 2, an interlayer dielectric layer 4 and a second conductive layer 3 sequentially arranged on the dielectric substrate 1. The first conductive layer 2 includes a first conductive structure 21, the second conductive layer 3 includes a second conductive structure 31, and the first conductive structure 21 and the second conductive structure 31 are electrically connected to each other through a connection hole 41 penetrating through at least the interlayer dielectric layer 4 between the first conductive structure 21 and the second conductive structure 31. In this example, the connection hole 41 includes a first sub-hole 401 and a second sub-hole 402 that are communicated with each other; the first sub-hole 401 penetrates through the interlayer dielectric layer 4, and the second sub-hole 402 penetrates through at least a part of a thickness of the first conductive structure 21. That is, the connection hole 41 penetrates through not only the interlayer dielectric layer 4 but also at least a part of the thickness of the first conductive structure 21. In this case, during the second conductive structure 31 being connected to the first conductive structure 21, the connection position between the second conductive structure 31 and the first conductive structure 21 is defined in the second sub-hole 402, so that, even if the interlayer dielectric layer 4 expands laterally, the connection position between the second conductive structure 31 and the first conductive structure 21 is defined in the second sub-hole in the first conductive structure 21, and the separation (peeling) at the connection position between the second conductive structure 31 and the first conductive structure 21 can be effectively avoided.

In some examples, a first opening of the first sub-hole 401 is connected to a second opening of the second sub-hole 402, and orthographic projections of the first opening and the second opening on the dielectric substrate 1 completely coincide, and in this case, the connection position between the second conductive structure 31 and the first conductive structure 21 is completely covered by the second sub-hole, which can ensure that the second conductive structure 31 and the first conductive structure 21 are stably connected together. It should be noted that, in the embodiment of the present disclosure, the first opening of the first sub-hole 401 refers to one of the two openings of the first sub-hole 401 that is close to the dielectric substrate 1, and the second opening of the second sub-hole 402 refers to one of the two openings of the second sub-hole 402 that is away from the dielectric substrate 1. In this case, shapes of the orthographic projections of the first sub-hole 401 and the second sub-hole 402 on the dielectric substrate 1 are identical. For example, if the shape of the orthographic projection of the first sub-hole 401 on the dielectric substrate 1 is circular, the shape of the orthographic projection of the second sub-hole 402 on the dielectric substrate 1 is also circular.

FIG. 4b is a cross-sectional view illustrating a connection hole of the integrated passive device shown in FIG. 3. In some examples, as shown in FIG. 4b, the first opening of the first sub-hole 401 is connected to the second opening of the second sub-hole 402, and the orthographic projection of the second opening on the dielectric substrate 1 covers the orthographic projection of the first opening on the dielectric substrate 1. In this case, the second sub-hole 402 has a larger aperture than an aperture of the first sub-hole 401. In this case, the shapes of the orthographic projections of the first sub-hole 401 and the second sub-hole 402 on the dielectric substrate 1 may be completely the same or may be different. For example, if the shape of the orthographic projection of the first sub-hole 401 on the dielectric substrate 1 is circular, the shape of the orthographic projection of the second sub-hole 402 on the dielectric substrate 1 is also circular. For another example, if the shape of the orthographic projection of the first sub-hole 401 on the dielectric substrate 1 is circular, the shape of the orthographic projection of the second sub-hole 402 on the dielectric substrate 1 is alternatively square.

FIG. 5 is a cross-sectional view illustrating a part of an integrated passive device including three conductive layers in a first example according to the embodiment of the present disclosure. It is noted that, as shown in FIG. 5, on the basis of the above example, it may be expanded that the integrated passive device includes more conductive layers, and in this case, a depth, a shape, and a size of the second sub-hole each may be the same or different for different conductive layers, which is not limited in the embodiment of the present disclosure.

For the integrated passive device in the first example, a method for manufacturing the integrated passive device is also provided in this example. FIG. 6 is a flowchart illustrating a method for manufacturing an integrated passive device in a first example according to the embodiment of the present disclosure. As shown in FIG. 6, the method may include the following steps S11 to S14.

Step S11, providing a dielectric substrate 1.

In some examples, a dielectric substrate 1, with a thickness ranging from 0.15 mm to 2 mm and applicable to mass production, is prepared according to the expectations of process equipment, a material of the dielectric substrate 1 may be selected from glass, high-resistivity silicon, ceramic, or any other high-insulating and low-dielectric-loss material. Step 11 may include a cleaning process before the dielectric substrate 1 has been prepared, so as to sequentially perform ultrasonic cleaning by using organic solvents including deionized water, ethanol, isopropyl alcohol and the like for at least 15 minutes, and then drying by an oven continuously at about 75° C. for a certain time duration depending on the final cleaning solvent.

Step S12, forming a first conductive layer 2 on the dielectric substrate 1, the first conductive layer 2 includes a first conductive structure 21, and the first conductive structure 21 includes a second sub-hole 402 penetrating through at least a part of a thickness of the first conductive structure 21.

In some examples, the first conductive layer 2 in step S12 may be formed by additive plating or subtractive plating. Step S12 will be described below, by taking forming the first conductive layer 2 by additive plating as an example.

Specifically, step S12 may include forming a first auxiliary film layer by a method including, but not limited to, magnetron sputtering, and then continuously sputtering to form a first conductive film layer, which serves as a first seed layer. Then, a first photoresist layer is formed on a side of the first seed layer away from the dielectric substrate 1, and exposure, development and etching are performed on the first photoresist layer, to form a first conductive pattern. The first conductive pattern is electroplated to form a first conductive structure 21 to be patterned. A second photoresist layer is formed on the first conductive structure 21 to be patterned, and exposure, development and etching are performed on the second photoresist layer to form the first conductive structure 21 with the second sub-hole 402.

The first auxiliary film layer is used for increasing the adhesion of the first conductive film layer. A material of the first auxiliary film layer includes, but is not limited to, titanium (Ti), and a material of the first conductive film layer includes, but is not limited to, copper (Cu). The first photoresist layer and the second photoresist layer may adopt common photosensitive photoresist, and positive photoresist or negative photoresist may be selected.

Step S13, forming an interlayer dielectric layer 4 on a side of the first conductive structure 21 away from the dielectric substrate 1, the interlayer dielectric layer 4 has a first sub-hole 401 penetrating through a thickness of the interlayer dielectric layer 4, and the first sub-hole 401 is communicated with the second sub-hole 402 to form a connection hole 41.

In some examples, a material of the interlayer dielectric layer 4 includes, for example, a resin material such as polyimide, epoxy resin, acryl, polyester, photoresist, polyacrylate, polyamide, siloxane, or the like, or for another example, an organic insulating material including an elastic material, such as ethyl carbamate, Thermoplastic Polyurethane (TPU), or the like. In the embodiment of the present disclosure, the interlayer dielectric layer 4 made of polyimide is taken as an example. Step S13 may include coating to form an interlayer dielectric layer 4 to be patterned, then forming the first sub-hole 401 penetrating through the interlayer dielectric layer 4 through exposure, development and etching, and finally curing the interlayer dielectric layer 4.

Step S14, forming a second conductive layer 3 on a side of the interlayer dielectric layer 4 away from the dielectric substrate 1, the second conductive layer 3 includes a second conductive structure 31, and the second conductive structure 31 is electrically connected to the first conductive structure 21 through the first sub-hole 401 and the second sub-hole 402.

In some examples, the second conductive layer 3 in step S14 may be formed by additive plating or subtractive plating. Step S14 will be described below, by taking forming the second conductive layer 3 by additive plating as an example.

Specifically, step S14 may include forming a second auxiliary film layer by a method including, but not limited to, magnetron sputtering, and then continuously sputtering to form a second conductive film layer, which serves as a second seed layer. Then, a third photoresist layer is formed on a side of the second seed layer away from the dielectric substrate 1, and exposure, development and etching are performed on the third photoresist layer to form a second conductive pattern. The second conductive pattern is electroplated to form the second conductive structure 31.

The second auxiliary film layer is used for increasing the adhesion of the second conductive film layer. A material of the second auxiliary film layer includes, but is not limited to, Ti, and a material of the second conductive film layer includes, but is not limited to, Cu. The third photoresist layer may adopt common photosensitive photoresist. and positive photoresist or negative photoresist may be selected.

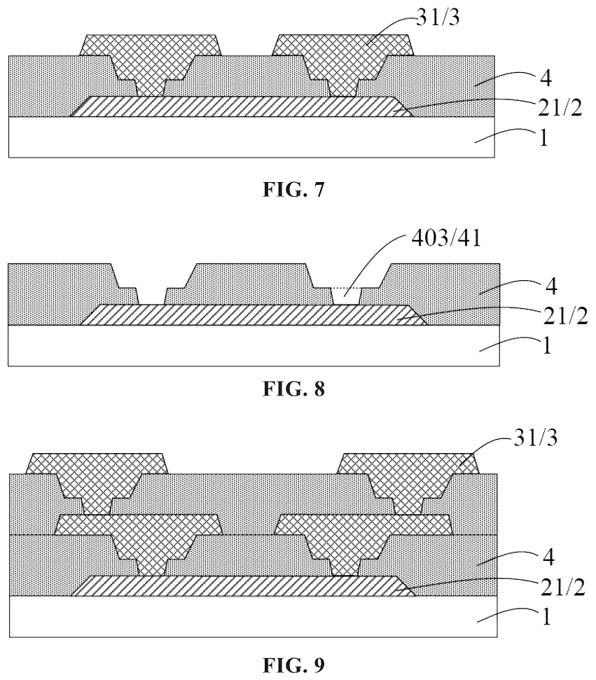

FIG. 7 is a cross-sectional view illustrating a part of an integrated passive device in a second example according to an embodiment of the present disclosure; and FIG. 8 is a cross-sectional view illustrating a connection hole of the integrated passive device shown in FIG. 7. As shown in FIGS. 7 and 8, in the second example, the integrated passive device includes a dielectric substrate 1, and a first conductive layer 2, an interlayer dielectric layer 4 and a second conductive layer 3 sequentially arranged on the dielectric substrate 1. The first conductive layer 2 includes a first conductive structure 21, the second conductive layer 3 includes a second conductive structure 31, and the first conductive structure 21 and the second conductive structure 31 are electrically connected to each other through a connection hole 41 penetrating through the interlayer dielectric layer 4. An inner wall of the connection hole 41 is stepped. In this example, the inner wall of the connection hole 41 is designed to be stepped, so that a contact area between the second conductive structure 31 and the interlayer dielectric layer 4 is increased. In this case, under the condition of being subjected to the same heat, the stress generated by expansion of the film layers is constant, since the contact area between the film layers is increased, the force applied to any unit area is reduced, and therfore separation between the film layers is more difficult to occur. Moreover, the heat dissipation area of the device is increased, and the heat accumulation at a local position is avoided.

In some embodiments, the connection hole 41 includes a plurality of sub-holes 403 which are communicated with each other, and the sub-holes 403 which are adjacently arranged define a step at the connection position therebetween, and a maximum aperture of the sub-hole 403 closer to the dielectric substrate 1 is less than a minimum aperture of the sub-hole 403 farther from the dielectric substrate 1.

Specifically, the interlayer dielectric layer 4 may include a plurality of first interlayer dielectric sub-layers 40 stacked together, each first interlayer dielectric sub-layer 40 has a sub-hole 403, and the sub-holes 403 are communicated with each other to form a connection hole 41. It should be noted that, in this example, only the connection hole 41 including two sub-holes 403, that is, the interlayer dielectric layer 4 including only two first interlayer dielectric sub-layers 40 is taken as an example. It should be understood that the number of the sub-holes 403 may be set as desired by the actual product, and is not listed here one by one.

FIG. 9 is a cross-sectional view illustrating a part of an integrated passive device including three conductive layers in a second example according to an embodiment of the present disclosure; It is noted that, as shown in FIG. 9, on the basis of the above example, it may be expanded that the integrated passive device includes more conductive layers, and a depth, a shape and a size of the connection hole 41 each may be the same or different for different interlayer dielectric layers 4, which is not limited in the embodiment of the present disclosure.

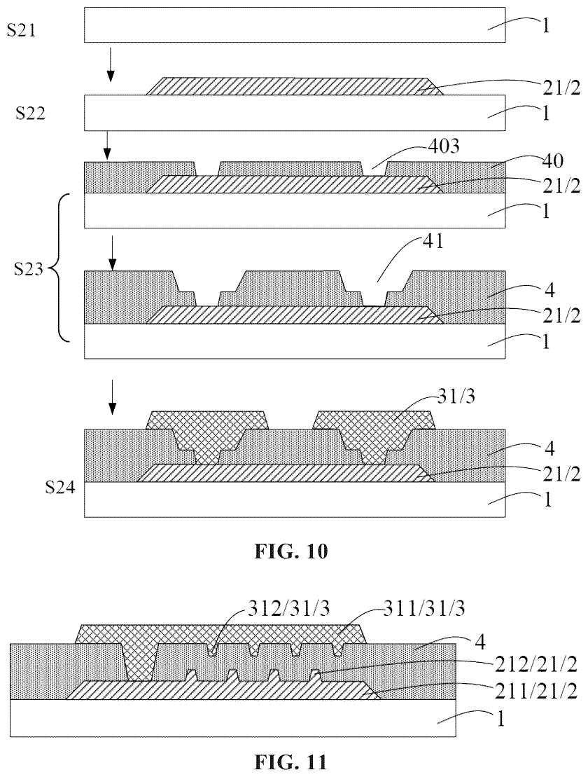

For the integrated passive device in the second example, a method for manufacturing the integrated passive device is also provided in this example. FIG. 10 is a flowchart illustrating a method for manufacturing an integrated passive device in a second example according to an embodiment of the present disclosure; and as shown in FIG. 10, the method may include the following steps S21 to S24.

Step S21, providing a dielectric substrate 1.

In some examples, a dielectric substrate 1, with a thickness ranging from 0.15 mm to 2 mm and applicable to mass production, is prepared according to the expectations of process equipment, a material of the dielectric substrate 1 may be selected from glass, high-resistivity silicon, ceramic, or any other high-insulating and low-dielectric-loss material. Step 21 may include a cleaning process before the dielectric substrate 1 has been prepared, so as to sequentially perform ultrasonic cleaning by using organic solvents including deionized water, ethanol, isopropyl alcohol and the like for at least 15 minutes, and then drying by an oven continuously at about 75° C. for a certain time depending on the final cleaning solvent.

Step S22, forming a first conductive layer 2 on the dielectric substrate 1, the first conductive layer 2 includes a first conductive structure 21.

In some examples, the first conductive layer 2 in step S22 may be formed by additive plating or subtractive plating. Step S22 will be described below, by taking forming the first conductive layer 2 by additive plating as an example.

Specifically, step S22 may include forming a first auxiliary film layer by a method including, but not limited to, magnetron sputtering, and then continuously sputtering to form a first conductive film layer, which serves as a first seed layer. Then, a first photoresist layer is formed on a side of the first seed layer away from the dielectric substrate 1, and exposure, development and etching are performed on the first photoresist layer to form a first conductive pattern. The first conductive pattern is electroplated to form a first conductive structure 21.

The first auxiliary film layer is used for increasing the adhesion of the first conductive film layer. A material of the first auxiliary film layer includes, but is not limited to, Ti, and a material of the first conductive film layer includes, but is not limited to, Cu. The first photoresist layer and the second photoresist layer may adopt common photosensitive photoresist, and positive photoresist or negative photoresist may be selected.

Step S23, forming an interlayer dielectric layer 4 on a side of the first conductive structure 21 away from the dielectric substrate 1, the interlayer dielectric layer 4 has a connection hole 41 penetrating through a thickness of the interlayer dielectric layer 4, the connection hole 41 includes a plurality of sub-holes 403 that are communicated with each other, and the sub-holes 403 that are adjacently arranged define a step at a connection position therebetween, and a maximum aperture of the sub-hole 403 closer to the dielectric substrate 1 is less than a minimum aperture of the sub-hole 403 farther from the dielectric substrate 1.

In some examples, the interlayer dielectric layer 4 may include a plurality of first interlayer dielectric sub-layers 40 stacked together, each first interlayer dielectric sub-layer 40 has a sub-hole 403, and a plurality of sub-holes 403 are communicated with each other to form a connection hole 41. A material of the first interlayer dielectric sub-layer 40 includes, for example, a resin material such as polyimide, epoxy resin, acryl, polyester, photoresist, polyacrylate, polyamide, siloxane, or the like, and for another example, an organic insulating material including an elastic material, such as ethyl carbamate, TPU, or the like.

In the embodiment of the present disclosure, the first interlayer dielectric sub-layer 40 made of polyimide is taken as an example. Step S23 may include coating to form a first first interlayer dielectric sub-layer 40 to be patterned, forming a sub-hole 403 penetrating through the first first interlayer dielectric sub-layer 40 through exposure, development and etching, and finally curing the first first interlayer dielectric sub-layer 40. Then, coating is continued to form a second first interlayer dielectric sub-layer 40 to be patterned, then, a sub-hole 403 penetrating through the second first interlayer dielectric sub-layer 40 is formed through exposure, development and etching, and finally, curing is performed, so that the connection hole 41 is formed.

Step S24, forming a second conductive layer 3 on a side of the interlayer dielectric layer 4 away from the dielectric substrate 1, the second conductive layer 3 includes a second conductive structure 31, and the second conductive structure 31 is electrically connected to the first conductive structure 21 through the first sub-hole 401 and the second sub-hole 402.

In some examples, the second conductive layer 3 in step S24 may be formed by additive plating or subtractive plating. Step S24 will be described below, by taking forming the second conductive layer 3 by additive plating as an example.

Specifically, step S24 may include forming a second auxiliary film layer by a method including, but not limited to, magnetron sputtering, and then continuously sputtering to form a second conductive film layer, which serves as a second seed layer. Then, a third photoresist layer is formed on a side of the second seed layer away from the dielectric substrate 1, and exposure, development and etching are performed on the third photoresist layer to form a second conductive pattern. The second conductive pattern is electroplated to form the second conductive structure 31.

The second auxiliary film layer is used for increasing the adhesion of the second conductive film layer. A material of the second auxiliary film layer includes, but is not limited to, Ti, and a material of the second conductive film layer includes, but is not limited to, Cu. The third photoresist layer may adopt common photosensitive photoresist, and positive photoresist or negative photoresist may be selected.

FIG. 11 is a cross-sectional view illustrating a part of an integrated passive device in a third example according to an embodiment of the present disclosure. As shown in FIG. 11, in the third example, the integrated passive device includes a dielectric substrate 1, and a first conductive layer 2, an interlayer dielectric layer 4 and a second conductive layer 3 sequentially arranged on the dielectric substrate 1. The first conductive layer 2 includes a first conductive structure 21, the second conductive layer 3 includes a second conductive structure 31, and the first conductive structure 21 and the second conductive structure 31 are electrically connected to each other through a connection hole 41 penetrating through at least the interlayer dielectric layer 4 between the first conductive structure 21 and the second conductive structure 31. In this example, the first conductive structure 21 includes a first body structure 211 and a plurality of first bump structures 212 connected to a side of the first body structure 211 close to the interlayer dielectric layer 4, and/or the second conductive structure 31 includes a second body structure 311 and a plurality of second bump structures 312 connected to a side of the second body structure 311 close to the interlayer dielectric layer 4. In the embodiment of the present disclosure, only the first conductive structure 21 including the first body structure 211 and the first bump structure 212, and the second conductive structure 31 including the second body structure 311 and the second bump structure 312 are taken as examples for explanation. In this case, the first body structure 211 and the second body structure 311 are electrically connected to each other through a connection hole 41 penetrating through the interlayer dielectric layer 4. The first bump structures 212 and the second bump structures 312 extend into the interlayer dielectric layer 4, and the interlayer dielectric layer 4 also extends into positions between the first bump structures 212 and between the second bump structures 312. Under the condition of being subjected to the same heat, stress generated by expansion of the film layers is constant, since a contact area between the film layers is increased, the force applied to any unit area is reduced, and therefore separation between the film layers is more difficult to occur. Moreover, the heat dissipation area of the device is increased, and heat accumulation at a local position is avoided.

In some examples, orthographic projections of the first bump structures 212 and the second bump structures 312 on the dielectric substrate 1 may be staggered, and alternatively, the first bump structures 212 and the second bump structures 312 may be arranged in a one-to-one correspondence. The problem of separation between the film layers can be alleviated regardless of any arrangement.

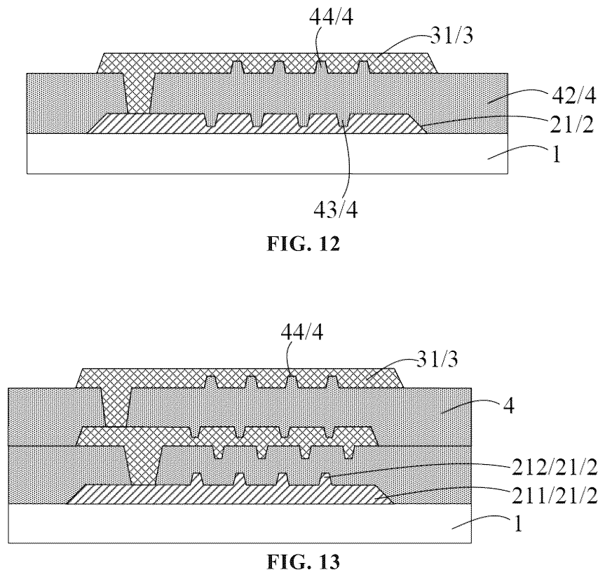

FIG. 12 is a cross-sectional view illustrating a part of another integrated passive device in a third example according to an embodiment of the present disclosure. As shown in FIG. 12, similar to the above example, the interlayer dielectric layer 4 of the integrated passive device may include a third body structure 42, a third bump structure 43 connected to a side of the third body structure 42 close to the first conductive structure 21, and a fourth bump structure 44 connected to a side of the third body structure 42 close to the second conductive structure 31. It should be understood that a second accommodation groove may be arranged in the first conductive structure 21, and a third accommodation groove may be arranged in the second conductive structure 31, so that the second accommodation groove(s) is in one-to-one correspondence with the third bump structure(s) 43, the third bump structure 43 is in the second accommodation groove corresponding thereto, the third accommodation groove(s) is in one-to-one correspondence with the fourth bump structure(s) 44, and the fourth bump structure 44 is in the third accommodation groove corresponding thereto.

FIG. 13 is a cross-sectional view illustrating a part of an integrated passive device including three conductive layers according to a third example of the embodiment of the present disclosure. It is noted that, as shown in FIG. 13, on the basis of the above example, it may be expanded that the integrated passive device includes more conductive layers, and in this case, a height, a shape, and a size of the bump structure each may be the same or different for different conductive layers, which is not limited in the embodiment of the present disclosure.

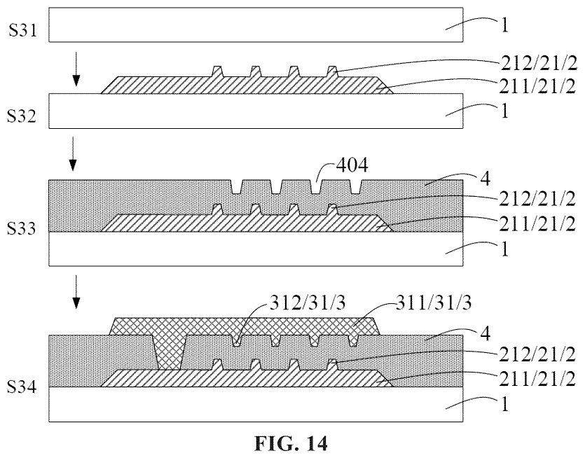

For the integrated passive device in the third example, a method for manufacturing the integrated passive device is also provided in this example. FIG. 14 is a flowchart illustrating a method for manufacturing an integrated passive device in a third example according to an embodiment of the present disclosure; and as shown in FIG. 14, the method may include the following steps S31 to S34.

Step S31, providing a dielectric substrate 1.

In some examples, a dielectric substrate 1, with a thickness ranging from 0.15 mm to 2 mm and applicable to mass production, is prepared according to the expectations of process equipment, a material of the dielectric substrate 1 may be selected from glass, high-resistivity silicon, ceramic, or any other high-insulating and low-dielectric-loss material. Step S31 may include a cleaning process before the dielectric substrate 1 has been prepared, so as to sequentially perform ultrasonic cleaning by using organic solvents including deionized water, ethanol, isopropyl alcohol and the like for at least 15 minutes, and then drying by an oven continuously at about 75° C. for a certain time depending on the final cleaning solvent.

Step S32, forming a first conductive layer 2 on the dielectric substrate 1, the first conductive layer 2 includes a first conductive structure 21; the first conductive structure 21 includes a first body structure 211 and a first bump structure 212.

In some examples, the first conductive layer 2 in step S32 may be formed by additive plating or subtractive plating. Step S32 will be described below, by taking forming the first conductive layer 2 by additive plating as an example.

Specifically, step S32 may include forming a first auxiliary film layer by a method including, but not limited to, magnetron sputtering, and then continuously sputtering to form a first conductive film layer, which serves as a first seed layer. Then, a first photoresist layer is formed on a side of the first seed layer away from the dielectric substrate 1, and exposure, development and etching are performed on the first photoresist layer to form a first conductive pattern. The first conductive pattern is electroplated to form a first body structure 211 to be patterned. A second photoresist layer is formed on the first body structure 211, and exposure, development and etching are performed on the second photoresist layer to expose a position, where the first bump structure 212 is to be formed, on the first body structure 211, and electroplating is performed to form the first bump structure 212, with the first body structure 211 at the position seving as a seed layer.

The first auxiliary film layer is used for increasing the adhesion of the first conductive film layer. A material of the first auxiliary film layer includes, but is not limited to, Ti, and a material of the first conductive film layer includes, but is not limited to, Cu. The first photoresist layer and the second photoresist layer may adopt common photosensitive photoresist, and positive photoresist or negative photoresist may be selected.

Step S33, forming an interlayer dielectric layer 4 on a side of the first conductive structure 21 away from the dielectric substrate 1, the interlayer dielectric layer 4 bas a connection hole 41 penetrating through a thickness of the interlayer dielectric layer 4, and a first accommodation groove 404 penetrating through a part of the thickness of the interlayer dielectric layer 4.

In some examples, a material of the interlayer dielectric layer 4 includes, for example, a resin material such as polyimide, epoxy resin, acryl, polyester, photoresist, polyacrylate, polyamide, siloxane, or the like, and for another example, an organic insulating material including an elastic material, such as ethyl carbamate, TPU, or the like. In the embodiment of the present disclosure, the interlayer dielectric layer 4 made of polyimide is taken as an example. Step S33 may include coating to form an interlayer dielectric layer 4 to be patterned, then forming the first sub-hole 401 penetrating through the interlayer dielectric layer 4 through exposure, development and etching, and finally curing the interlayer dielectric layer 4.

Step S34, forming a second conductive layer 3 on a side of the interlayer dielectric layer 4 away from the dielectric substrate 1, the second conductive layer 3 includes a second conductive structure 31, and the second conductive structure 31 includes a second body structure 311 and a second bump structure 312; the second body structure 311 is electrically connected to the first body structure 211 through the connection hole 41, the second bump structure(s) 312 is in one-to-one correspondence with the first accommodation groove(s) 404, and the second bump structure 312 is filled in the first accommodation groove 404 corresponding to the second bump structure 312.

In some examples, the second conductive layer 3 in step S34 may be formed by additive plating or subtractive plating. Step S34 will be described below, by taking forming the second conductive layer 3 by additive plating as an example.

Specifically, step S34 may include forming a second auxiliary film layer by a method including, but not limited to, magnetron sputtering, and then continuously sputtering to form a second conductive film layer, which serves as a second seed layer. Then, a third photoresist layer is formed on a side of the second seed layer away from the dielectric substrate 1, and exposure, development and etching are performed on the third photoresist layer to form a second conductive pattern. The second conductive pattern is electroplated to form the second conductive structure 31.

The second auxiliary film layer is used for increasing the adhesion of the second conductive film layer. A material of the second auxiliary film layer includes, but is not limited to, Ti, and a material of the second conductive film layer includes, but is not limited to, Cu. The third photoresist layer may adopt common photosensitive photoresist, and positive photoresist or negative photoresist may be selected.

In a second aspect, an embodiment of the present disclosure provides an electronic apparatus, including the integrated passive device described above.

It will be understood that the above embodiments are merely exemplary embodiments adopted to illustrate the principles of the present disclosure, and the present disclosure is not limited thereto. It will be apparent to one of ordinary skill in the art that various modifications and improvements may be made without departing from the scope of the present disclosure, and such modifications and improvements are also considered to be within the scope of the present disclosure.

1. An integrated passive device, comprising a dielectric substrate, at least two conductive layers on the dielectric substrate, and an interlayer dielectric layer between any two adjacent ones of the at least two conductive layers; wherein one of any two adjacent conductive layers close to the dielectric substrate is a first conductive layer, and the other one of the any two adjacent conductive layers is a second conductive layer;
wherein the first conductive layer comprises a first conductive structure, and the second conductive layer comprises a second conductive structure; the second conductive structure and the first conductive structure are electrically connected to each other through a connection hole penetrating through at least the interlayer dielectric layer between the second conductive structure and the first conductive structure.

2. The integrated passive device according to claim 1, wherein the connection hole comprises a first sub-hole and a second sub-hole communicated with each othe; the first sub-hole penetrates through the interlayer dielectric layer, and the second sub-hole penetrates through at least a part of a thickness of the first conductive structure.

3. The integrated passive device according to claim 2, wherein a first opening of the first sub-hole is connected to a second opening of the second sub-hole, and orthographic projections of the first opening and the second opening on the dielectric substrate coincide each other.

4. The integrated passive device according to claim 2, wherein a first opening of the first sub-hole is connected to a second opening of the second sub-hole, and an orthographic projection of the second opening on the dielectric substrate covers an orthographic projection of the first opening on the dielectric substrate.

5. The integrated passive device according to claim 2, wherein a shape of an orthographic projection of the second sub-hole on the dielectric substrate comprises a circle or a square.

6. The integrated passive device according to claim 1, wherein an inner wall of the connection hole is stepped.

7. The integrated passive device according to claim 6, wherein the connection hole comprises a plurality of sub-holes communicated with each othe, any two adjacent ones of the plurality of sub-holes define a step at a connection position therebetween, and a maximum aperture of the sub-hole closer to the dielectric substrate is less than a minimum aperture of the sub-hole farther from the dielectric substrate.

8. The integrated passive device according to claim 6, wherein the connection hole penetrats through only the interlayer dielectric layer.

9. The integrated passive device according to claim 1, wherein the first conductive structure comprises a first body structure and a first bump structure connected to a side of the first body structure close to the interlayer dielectric layer; and/or
the second conductive structure comprises a second body structure and a second bump structure connected to a side of the second body structure close to the interlayer dielectric layer.

10. The integrated passive device according to claim 9, wherein the first conductive structure comprises the first body structure and the first bump structure, the second conductive structure comprises the second body structure and the second bump structure, and the first body structure and the second body structure are connected to each other through the connection hole.

11. The integrated passive device according to claim 9, wherein the first conductive structure comprises the first body structure and the first bump structure, the second conductive structure comprises the second body structure and the second bump structure, and orthographic projections of the first bump structure and the second bump structure on the dielectric substrate are alternately arranged.

12. The integrated passive device according to claim 9, wherein the first conductive structure comprises the first body structure and the first bump structure, the second conductive structure comprises the second body structure and the second bump structure, and the first bump structure and the second bump structure are in one-to-one correspondence.

13. The integrated passive device according to claim 1, wherein the interlayer dielectric layer comprises a third body structure, a third bump structure connected to a side of the third body structure close to the first conductive structure, and a fourth bump structure connected to a side of the third body structure close to the second conductive structure.

14. The integrated passive device according to claim 1, wherein a material of the interlayer dielectric layer comprises polyimide.

15. A method for manufacturing an integrated passive device, comprising: providing a dielectric substrate, forming at least two conductive layers on the dielectric substrate, and forming an interlayer dielectric layer between any two adjacent ones of the at least two conductive layers; wherein one of any two adjacent conductive layers close to the dielectric substrate is a first conductive layer, and the other one of the any two adjacent conductive layers is a second conductive layer; wherein
forming the first conductive layer comprises forming a first conductive structure, forming the second conductive layer comprises forming a second conductive structure, and the second conductive structure and the first conductive structure are electrically connected to each other through a connection hole penetrating through at least the interlayer dielectric layer between the second conductive structure and the first conductive structure.

16. The method according to claim 15, wherein forming the connection hole comprises:
patterning, before the interlayer dielectric layer is formed, the first conductive pattern, to form a second sub-hole penetrating through at least a part of a thickness of the first conductive pattern; and
forming, after the interlayer dielectric layer is formed, a first sub-hole penetrating through the interlayer dielectric layer, wherein the first sub-hole and the second sub-hole are communicated with each other to form the connection hole.

17. The method according to claim 15, wherein forming the interlayer dielectric layer comprises sequentially stacking first interlayer dielectric sub-layers along a direction away from the dielectric substrate; each first interlayer dielectric sub-layer is provided with a sub-hole, and sub-holes of the first interlayer dielectric sub-layers are communicated with each other to form the connection hole; any two adjacent ones of the sub-holes define a step at a connection position therebetween, and a maximum aperture of the sub-hole closer to the dielectric substrate is less than a minimum aperture of the sub-hole farther from the dielectric substrate.

18. The method according to claim 15, wherein the first conductive structure comprises a first body structure, and a first bump structure connected to a side of the first body structure close to the interlayer dielectric layer; and/or
the second conductive structure comprises a second body structure and a second bump structure connected to a side of the second body structure close to the interlayer dielectric layer.

19. The method according to claim 15, wherein the conductive layer is formed through an electroplating process.

20. An electronic apparatus, comprising the integrated passive device according to claim 1.
